(19) United States
(12) Patent Application Publication
(10) Pub. No.: US 2011/0304395 A1
(43) Pub. Date: Dec. 15, 2011

(54) POWER AMPLIFIER

(75) Inventors: Bon Hoon KOO, Daejeon (KR); Ki Yong SON, Daejeon (KR); Song Cheol HONG, Daejeon (KR); Gyu Suck KIM, Seoul (KR); Yoo Sam NA, Seoul (KR)

(73) Assignees: KOREA ADVANCED INSTITUTE OF SCIENCE AND TECHNOLOGY, Daejeon (KR); SAMSUNG ELECTRO-MECHANICS CO., LTD., Gyunggi-do (KR)

(21) Appl. No.: 13/006,920

(22) Filed: Jan. 14, 2011

(30) Foreign Application Priority Data
Jun. 10, 2010 (KR) 10-2010-0054818

(51) Int. Cl. H03F 3/45; H03F 3/68; H03F 1/22; H03F 3/16

(52) U.S. Cl. 330/253; 330/299; 330/296

(57) ABSTRACT

Disclosed is a power amplifier. A power amplifier according to an aspect of the invention may include: a first amplification section having a first N metal oxide semiconductor (MOS) amplifier and a second N MOS amplifier connected in a cascode configuration and amplifying an input signal; a second amplification section having a first P MOS amplifier and a second P MOS amplifier connected in a cascode configuration and amplifying the input signal; and a power combining section combining respective output signals of the first amplification section and the second amplification section.

### CROSS-REFERENCE TO RELATED APPLICATIONS

This application claims the priority of Korean Patent Application No. 10-2010-0054818 filed on Jun. 10, 2010, in the Korean Intellectual Property Office, the disclosure of which is incorporated herein by reference.

### BACKGROUND OF THE INVENTION

1. Field of the Invention

The present invention relates to a power amplifier, and more particularly, to a power amplifier that has an N MOS amplification unit and a P MOS amplification unit connected in parallel with each other to compensate an input capacitance being varied according to operating modes and increase efficiency at a back-off point.

2. Description of the Related Art

Recently, various types of circuits of wireless transceivers have been manufactured using complementary metal oxide semiconductor (CMOS) technology. Though these circuits are integrated into a single chip, power amplifiers are manufactured using InGaP/GaAs heterojunction bipolar transistor (HBT) technology. However, this InGaP/GaAs HBT technology may cause higher manufacturing costs when compared with the CMOS process and be formed only in multichip structures. Besides, it is difficult to combine power amplifiers, manufactured using InGaP/GaAs HBT technology, with adjustment circuits, manufactured using the CMOS process.

For these reasons, research has been conducted into power amplifiers manufactured by using the CMOS process.

Meanwhile, performance indicators for evaluating linear power amplifiers may include the maximum output power up to a point at which linearity is satisfied, maximum efficiency, and efficiency at a point at which a back-off is performed at the maximum output power. However, in comparison with power amplifiers manufactured by an HBT process, power amplifiers manufactured by a CMOS process have poor performance.

### SUMMARY OF THE INVENTION

An aspect of the present invention provides a power amplifier that has an N MOS amplification unit and a P MOS amplification unit connected in parallel with each other to compensate an input capacitance being varied according to operating modes and increase efficiency at back-off point.

According to an aspect of the present invention, there is provided a power amplifier including: a first amplification section having a first N metal oxide semiconductor (MOS) amplifier and a second N MOS amplifier connected in a cascode configuration and amplifying an input signal; a second amplification section having a first P MOS amplifier and a second P MOS amplifier connected in a cascode configuration and amplifying the input signal; and a power combining section combining respective output signals of the first amplification section and the second amplification section.

The first amplification section may be turned on in a first operating mode operating within a first power level range set beforehand, the second amplification section may be turned on in a second operating mode, set beforehand, operating within a second power level range set to be lower than that of the first operating mode, and the first and second amplification sections may be turned on in a third operating mode, set beforehand, operating within a third power level range set to be higher than that of the first operating mode.

The first amplification section may include: a first gate power supply unit supplying a predetermined gate power to a gate of the first N MOS amplifier; and a first bias power supply unit supplying a predetermined bias power to a drain of the first N MOS amplifier.

The second amplification section may supply the predetermined gate power to a gate of the second P MOS amplifier and supply the predetermined bias power to a source of the first PMOS amplifier.

The input signal may be input to a gate of the second N MOS amplifier of the first amplification section and a gate of the first P MOS amplifier of the second amplification section, and the second amplification section may further include a blocking capacitor connected to the gate of the first PMOS amplifier of the second amplification section to thereby transmit the input signal to the gate of the first P MOS amplifier and block unnecessary power.

According to another aspect of the present invention, there is provided a power amplifier including: a first amplification section having a first amplification unit including a first N metal oxide semiconductor (MOS) amplifier and a second N MOS amplifier connected in a cascode configuration to amplify an input signal and a second amplification unit including a third N MOS amplifier and a fourth N MOS amplifier connected in parallel with the first amplification unit and connected in a cascode configuration to amplify a differential signal being input; a second amplification having a third amplification unit including a first P MOS amplifier and a second P MOS amplifier connected in a cascode configuration to amplify the input signal and a fourth amplification unit including a third P MOS amplifier and a fourth P MOS amplifier connected in parallel with the third amplification unit to amplify the differential signal; and a power combining section combining respective output signals of the first amplification section and the second amplification section.

The first amplification section may be turned on in a first operating mode operating within a first power level range set beforehand, the second amplification section may be turned on in a second operating mode operating within a second power level range set to be lower than that of the first operating mode, and the first and second amplification sections may be turned on in a third operating mode operating within a third power level range set to be higher than that of the first operating mode.

A gate of the first N MOS amplifier of the first amplification unit of the first amplification section and a gate of the third N MOS amplifier of the second amplification unit may be connected in common to each other, the differential signal may be input to each of a gate of the second N MOS amplifier of the first amplification unit and a gate of the fourth N MOS amplifier of the second amplification unit, and a source of the second N MOS amplifier of the first amplification unit and a source of the fourth N MOS amplifier of the second amplification unit may be connected to a ground terminal.

A gate of the second P MOS amplifier of the third amplification unit of the second amplification section and a gate of the fourth P MOS amplifier of the fourth amplification unit may be connected in common to each other, the differential signal may be input to each of a gate of the first P MOS amplifier of the third amplification unit and a gate of the third P MOS amplifier of the fourth amplification unit, and a source of the first P MOS amplifier of the third amplification unit and a source of the third P MOS amplifier of the fourth amplification unit may be connected in common to a driving power terminal through which a predetermined driving power is supplied.

The second amplification section may further include a first blocking capacitor transmitting the differential signal to the gate of the first P MOS amplifier of the third amplification unit and blocking unnecessary power, and a second blocking capacitor transmitting the differential signal to the gate of the third P MOS amplifier of the fourth amplification unit and blocking unnecessary power.

The power amplifier may further include a first balun converting an input signal being externally applied into the differential signal.

The power amplifier may further include: a second balun converting the differential Signal, amplified by the first amplification section, into a single signal and transmitting the single signal to the power combining section; and a third balun converting the differential signal, amplified by the second amplification section, into a single signal and transmitting the single signal to the power combining section.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic configuration view illustrating a power amplifier according to an exemplary embodiment of the present invention;

FIG. 2 is a schematic view illustrating an internal configuration of a power amplifier according to another exemplary embodiment of the present invention;

FIG. 3 is a graph illustrating electrical characteristics in which an input capacitance is compensated by a power amplifier according to an exemplary embodiment of the present invention;

FIG. 4 is a graph illustrating electrical characteristics in which efficiency is increased in a back-off area by a power amplifier according to an exemplary embodiment of the present invention; and

FIG. 5 is a diagram illustrating an integrated circuit of a power amplifier according to an exemplary embodiment of the present invention.

### DETAILED DESCRIPTION OF THE PREFERRED EMBODIMENT

Exemplary embodiments of the present invention will now be described in detail with reference to the accompanying drawings.

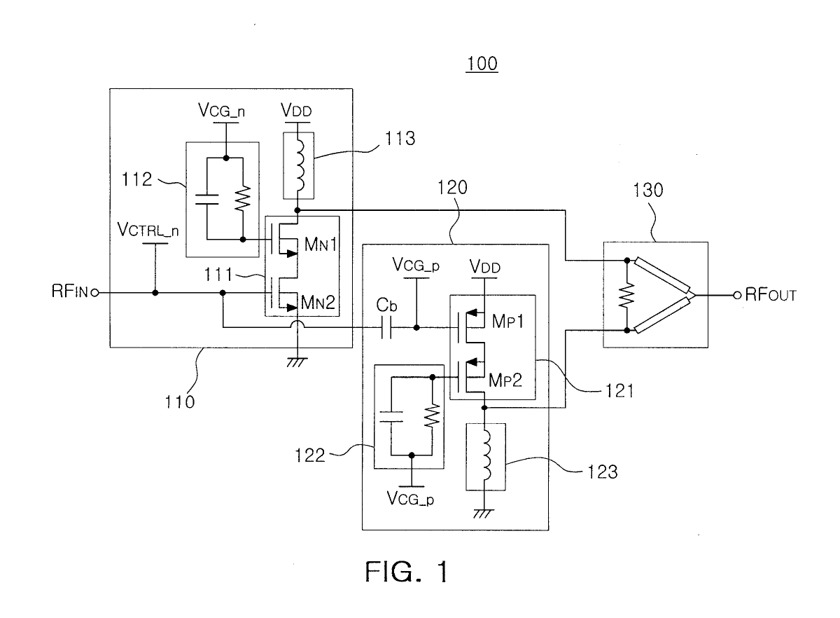

FIG. 1 is a schematic configuration view illustrating a power amplifier according to an exemplary embodiment of the invention.

Referring to FIG. 1, a power amplifier 100 according to this embodiment may include a first amplification section 110, a second amplification section 120, and a power combining section 130.

The first amplification section 110 may include an amplification unit 111, a first gate power supply unit 112 and a first bias power supply unit 113.

The amplification unit 111 may include a first N metal oxide semiconductor (MOS) amplifier MN1 and a second N MOS amplifier MN2 connected in a cascode configuration.

A first gate power having a predetermined voltage level is supplied to a gate of the first N MOS amplifier MN1, while a bias power having a predetermined level is supplied to a drain of the first N MOS amplifier MN1.

The first gate power supply unit 112 may include a resistor and a capacitor, which are connected to a first gate power V_{G}_{_{—}}ₙ terminal and are connected in parallel with each other, to thereby supply the first gate power to the gate of the first N MOS amplifier MN1.

The first bias power supply unit 113 is composed of an inductor connected to a bias power V_{DD} terminal. The first bias power supply unit 113 may supply the bias power to the drain of the first N MOS amplifier MN1 and block an unnecessary signal.

An input signal RE_{IN} is input to a gate of the second N MOS amplifier MN2, a source of the second N MOS amplifier MN2 is connected to a ground terminal, and a drain of the second N MOS amplifier MN2 is connected to a source of the first N MOS amplifier MN1.

A control signal V_{CTRL}_{_{—}}ₙ is externally input to the gate of the second N MOS amplifier MN2 to turn the amplification unit 111 of the first amplification section 110 on or off.

The second amplification section 120 may include an amplification unit 121 and a second gate power supply unit 122.

The amplification unit 121 may include a first P MOS amplifier MP1 and a second P MOS amplifier MP2 connected in a cascode configuration.

A second gate power having a predetermined voltage level is supplied to a gate of the second P MOS amplifier MP2, while the bias power V_{DD} having the predetermined voltage level is supplied to a source of the first P MOS amplifier MP1.

The second gate power supply unit 122 includes a resistor and a capacitor, which are connected in parallel with each other and are connected to a second gate power V_{CG}_{_{—}}ₚ terminal, to thereby supply the second gate power to the gate of the second P MOS amplifier MP2.

An inductor may be connected between the drain of the second P MOS amplifier MP2 and a drain terminal and block unnecessary signals.

The input signal RF_{IN} is input to a gate of the first P MOS amplifier MP1, the bias power V_{DD} is input to the source of the first P MOS amplifier MP1, and a drain of the first P MOS amplifier MP1 is connected to a source of the second P MOS amplifier MP2.

A control signal V_{CTRL}_{_{—}}ₚ is externally input to the gate of the first P MOS amplifier MP1, thereby turning the amplification unit 121 of the second amplification section 120 on or off.

The second amplification section 120 may further include a blocking capacitor Cb that transmits the input signal RF_{IN} to the first P MOS amplifier MP1 and blocks the transmission of the control signal V_{CTRL}_{_{—}}ₙ.

The power combining section 130 combines an output signal being output through the drain of the first N MOS amplifier MN1 of the first amplification section 110 and an output signal being output through the drain of the second P MOS amplifier MP2 of the second amplification section 120 into a single output signal RF_{OUT}.

As described above, the power amplifier 100 according to this embodiment may turn the amplification unit 111 of the first amplification section 110 and the amplification unit 121 of the second amplification section 120 on or off according to the control signals V_{CTRL}_{_{—}}ₙ and V_{CTRL}_{_{—}}ₚ.

That is, in a first level range having a predetermined power level, the amplification unit 111 of the first amplification section 110 is turned on, while the amplification unit 121 of the second amplification section 120 is turned off. In a second level range whose power level is lower than that of the first level range since a back-off value is set to be high, the amplification unit 111 of the first amplification section is turned off, while the amplification unit 121 of the second amplification section 120 is turned on so that only the P MOS amplifier having relatively small mobility is used to thereby improve efficiency.

In a third level range whose power level range is higher than that of the first level range, that is, where the maximum output power is required, both the amplification unit 111 of the first amplification section 110 and the amplification unit 121 of the second amplification section 120 are turned on.

At this time, as the amplification unit 111 of the first amplification section 110 and the amplification unit 121 of the second amplification section 120 are connected in parallel with each other, a voltage level difference between the control signals V_{CTRL}_{_{—}}ₙ and V_{CTRL}_{_{—}}ₚ is reduced to thereby offset capacitance variations.

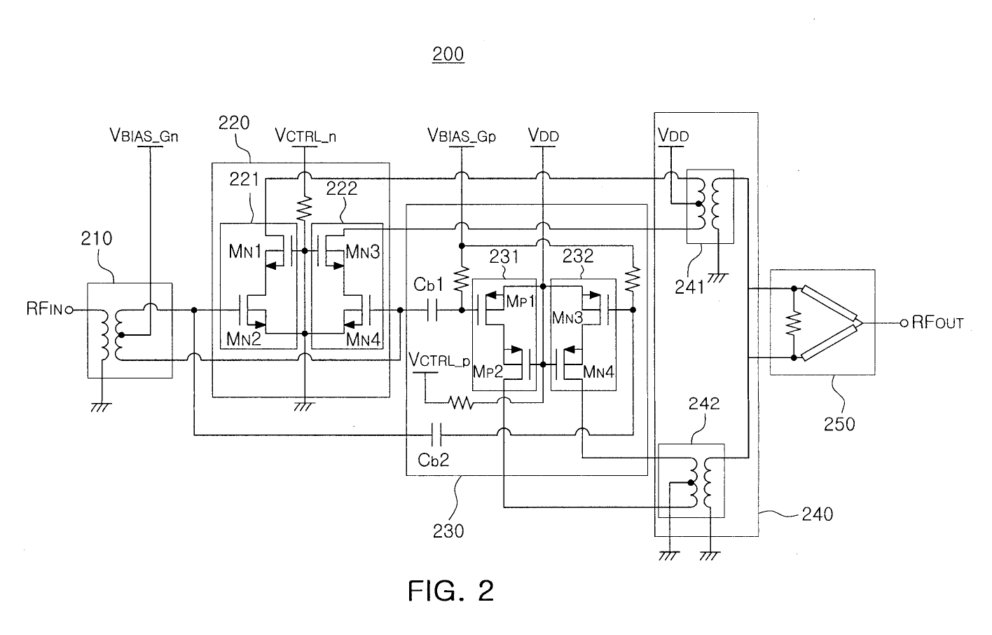

FIG. 2 is a schematic view illustrating an internal configuration of a power amplifier according to another exemplary embodiment of the invention.

Referring to FIG. 2, a power amplifier 200 according to this embodiment may include a first amplification section 220, a second amplification section 230, and a power combining section 250 receiving a differential signal. The power amplifier 200 may further include a balun group 240 that includes a first balun 210 converting an input signal into the differential signal and second and third baluns 241 and 242 each converting the differential signal, being output from the second amplification section 230, into a single signal.

The first amplification section 220 may include first and second amplification units 221 and 222. The first amplification unit 221 may include first and second N MOS amplifiers MN1 and MN2 connected in a cascode configuration, and the second amplification unit 222 may include third and fourth N MOS amplifiers MN3 and MN4 connected in a cascode configuration.

A bias power V_{DD} is applied to respective drains of the first N MOS amplifier MN1 and the third N MOS amplifier MN3, which then output amplified signals. Gates of the first N MOS amplifier MN1 and the third N MOS amplifier MN3 are connected in common to each other to which a control signal V_{CTRL}_{_{—}}ₙ is input.

Sources of the second N MOS amplifier MN2 and the fourth N MOS amplifier MN4 are commonly connected to a ground terminal. The differential signals are input to respective gates of the second N MOS amplifier MN2 and the fourth N MOS amplifier MN4. That is, one of the differential signals may be input to a gate of the second N MOS amplifier MN2, while the other may be input to a gate of the fourth N MOS amplifier MN4.

Furthermore, the differential signals may be input to the second amplification section 230.

The second amplification section 230 may include third and fourth amplification units 231 and 232. The third amplification unit 231 may include first and second P MOS amplifiers MP1 and MP2 connected in a cascode configuration, and the fourth amplification unit 232 may include third and fourth P MOS amplifiers MP3 and MP4 connected in a cascode configuration.

The bias power V_{DD} is applied to respective sources of the first P MOS amplifier MP1 and the third P MOS amplifier MP3. The differential signals are input to respective gates of the first P MOS amplifier MP1 and the third P MOS amplifier MP3. That is, one of the differential signals may be input to the gate of the first P MOS amplifier MP1, while the other may be input to the gate of the third P MOS amplifier MP3.

Drains of the second P MOS amplifier MP2 and the fourth P MOS amplifier MP4 output respective amplified signals. Gates of the second P MOS amplifier MP2 and the fourth P MOS amplifier MP4 are connected in common to each other to which a control signal V_{CTRL} is input.

The second amplification section 230 may further include first and second blocking capacitors Cb1 and Cb2. The first blocking capacitor Cb1 may transmit one of the differential signals to the gate of the first P MOS amplifier MP1 of the third amplification unit 231 and block unnecessary power, while the second blocking capacitor Cb2 may transmit the other differential signal to the gate of the third P MOS amplifier MP3 of the fourth amplification unit 232 and block unnecessary power.

The first balun 210 converts the input signal RF_{IN} into the differential signal. The second balun 241 of the balun group 240 converts the differential signal, amplified by the first amplification section 220, into a single signal. The third balun 242 converts the differential signal, amplified by the second amplification section 230, into a single signal. The power combining section 250 may combine the single signal from the second balun 241 and the single signal from the third balun 242 into a single output signal RF_{OUT}.

In the same manner, the power amplifier 200 according to this embodiment can turn the first and second amplification units 221 and 222 of the first amplification section 220 and the third and fourth amplification units 231 and 232 of the second amplification section 230 on or off according to the control signals V_{CTRL}_{_{—}}ₙ and V_{CTRL}_{_{—}}ₚ.

That is, in a first level range having a predetermined power level range, the first and second amplification units 221 and 222 of the first amplification section 220 are turned on, while the third and fourth amplification units 231 and 232 of the second amplification section 230 are turned off. In a second level range whose power level range is lower than that of the first level range, the first and second amplification units 221 and 222 of the first amplification section 220 are turned off, while the third and fourth amplification units 231 and 232 of the second amplification section 230 are turned on so that only the P MOS amplifier having relatively small mobility is turned on to thereby improve efficiency.

In a third level range whose power level range is higher than that of the first level range, that is, where the maximum output power is required, the first and second amplification units 221 and 222 of the first amplification section 220 and the third and fourth amplification units 231 and 232 of the second amplification section 230 may be turned on.

Here, as the first and second amplification units 221 and 222 of the first amplification section 220 and the third and fourth amplification units 231 and 232 of the second amplification section 230 are connected in parallel with each other, a voltage level difference between the control signals V_{CTRL}_{_{—}}ₙ and V_{CTRL}_{_{—}}ₚ is reduced to thereby offset input capacitance variations.

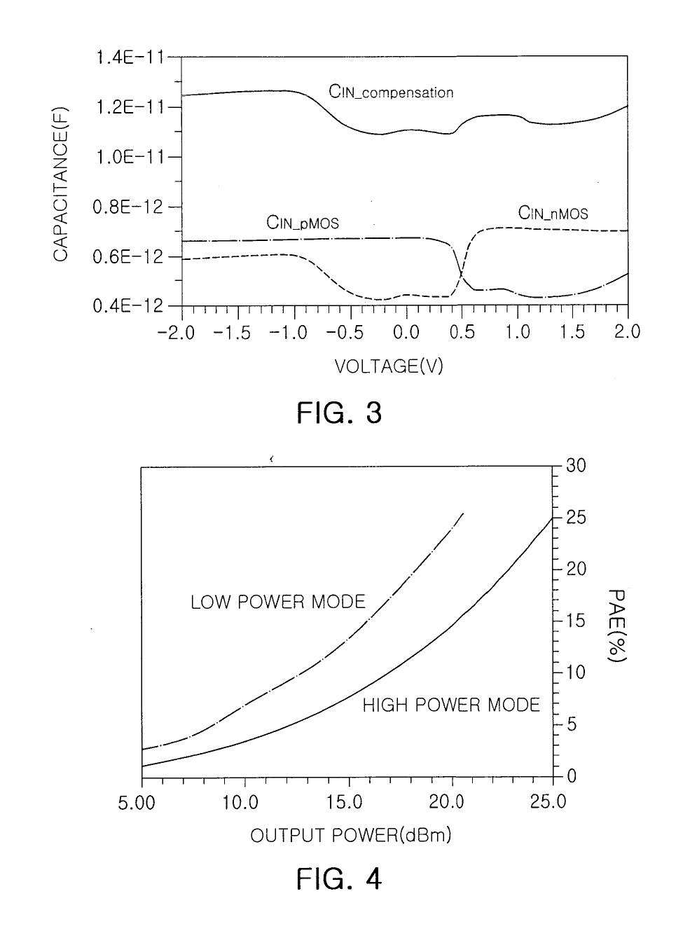

FIG. 3 is a graph illustrating electrical characteristics in which an input capacitance is compensated by a power amplifier according to an exemplary embodiment of the invention.

Referring to FIG. 3, when operating points of the N MOS amplifier and the P MOS amplifier are determined (when the control signals V_{CTRL}_{_{—}}ₚ and V_{CTRL}_{_{—}}ₙ have a voltage of approximately 2.5V), an input capacitance C_{IN}_{_{—}}_{nMOS} of the N MOS amplifier and an input capacitance C_{IN}_{_{—}}_{pMOS} of the P MOS amplifier offset each other, so that the variations of an input capacitance C_{IN}_{_{—}}_{compensation} are shown to be reduced.

FIG. 4 is a graph illustrating electrical characteristics in which efficiency is greatly increased in a back-off area by a power amplifier according to an exemplary embodiment of the invention.

Referring to FIG. 4, the power amplifier selectively operates the N MOS amplification unit or the P MOS amplification unit according to operating modes by the control signals V_{CTRL}_{_{—}}ₙ and V_{CTRL}_{_{—}}ₚ, so that efficiency is shown to be greatly increased at a low power point.

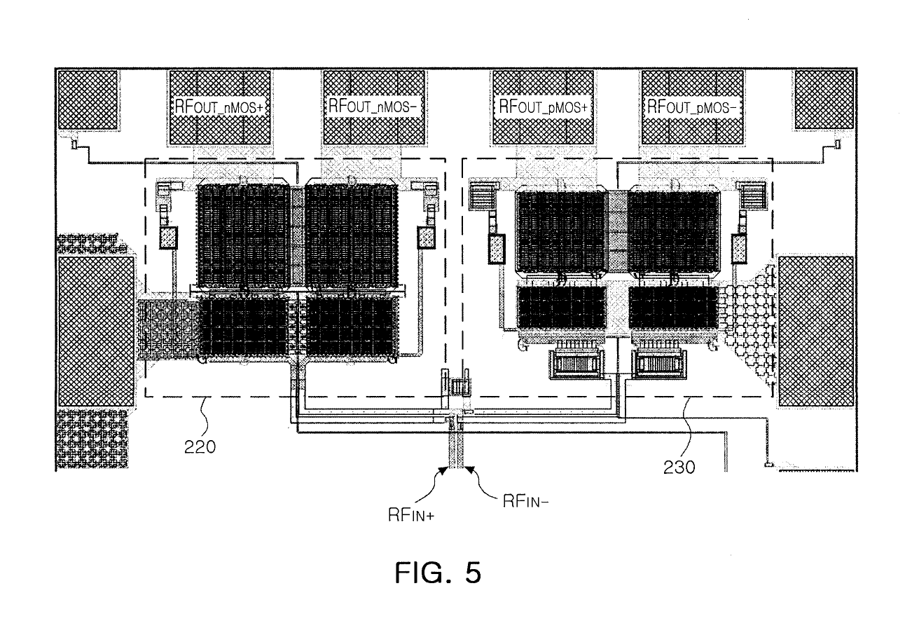

FIG. 5 is a diagram illustrating an integrated circuit of a power amplifier according to an exemplary embodiment of the invention.

Referring to FIG. 5, when a power amplifier has a differential structure, as shown in FIG. 2, only the first amplification section 220 and the second amplification section 230 are shown to be connected in parallel with each other.

As set forth above, according to exemplary embodiments of the invention, an N MOS amplification unit and a P MOS amplification unit are connected in parallel with each other, so that an input capacitance, being varied according to operating modes, can be compensated, and efficiency at back-off point can be improved.

While the present invention has been shown and described in connection with the exemplary embodiments, it will be apparent to those skilled in the art that modifications and variations can be made without departing from the spirit and scope of the invention as defined by the appended claims.

What is claimed is:

1. A power amplifier comprising:
a first amplification section having a first N metal oxide semiconductor (MOS) amplifier and a second N MOS amplifier connected in a cascode configuration and amplifying an input signal;
a second amplification section having a first P MOS amplifier and a second P MOS amplifier connected in a cascode configuration and amplifying the input signal; and
a power combining section combining respective output signals of the first amplification section and the second amplification section.

2. The power amplifier of claim 1, wherein the first amplification section is turned on in a first operating mode operating within a first power level range set beforehand,
the second amplification section is turned on in a second operating mode, set beforehand, operating within a second power level range set to be lower than that of the first operating mode, and
the first and second amplification sections are turned on in a third operating mode, set beforehand, operating within a third power level range set to be higher than that of the first operating mode.

3. The power amplifier of claim 1, wherein the first amplification section comprises:
a first gate power supply unit supplying a predetermined gate power to a gate of the first N MOS amplifier; and
a first bias power supply unit supplying a predetermined bias power to a drain of the first N MOS amplifier.

4. The power amplifier of claim 1, wherein the second amplification section supplies the predetermined gate power to a gate of the second P MOS amplifier and supplies the predetermined bias power to a source of the first PMOS amplifier.

5. The power amplifier of claim 4, wherein the input signal is input to a gate of the second N MOS amplifier of the first amplification section and a gate of the first P MOS amplifier of the second amplification section, and
the second amplification section further comprises a blocking capacitor connected to the gate of the first PMOS amplifier of the second amplification section to thereby transmit the input signal to the gate of the first P MOS amplifier and block unnecessary power.

6. A power amplifier comprising:
a first amplification section having a first amplification unit including a first N metal oxide semiconductor (MOS) amplifier and a second N MOS amplifier connected in a cascode configuration to amplify an input signal and a second amplification unit including a third N MOS amplifier and a fourth N MOS amplifier connected in parallel with the first amplification unit and connected in a cascode configuration to amplify a differential signal being input;
a second amplification having a third amplification unit including a first P MOS amplifier and a second P MOS amplifier connected in a cascode configuration to amplify the input signal and a fourth amplification unit including a third P MOS amplifier and a fourth P MOS amplifier connected in parallel with the third amplification unit to amplify the differential signal; and
a power combining section combining respective output signals of the first amplification section and the second amplification section.

7. The power amplifier of claim 6, wherein the first amplification section is turned on in a first operating mode operating within a first power level range set beforehand,
the second amplification section is turned on in a second operating mode operating within a second power level range set to be lower than that of the first operating mode, and
the first and second amplification sections are turned on in a third operating mode operating within a third power level range set to be higher than that of the first operating mode.

8. The power amplifier of claim 6, wherein a gate of the first N MOS amplifier of the first amplification unit of the first amplification section and a gate of the third N MOS amplifier of the second amplification unit are connected in common to each other,
the differential signal is input to each of a gate of the second N MOS amplifier of the first amplification unit and a gate of the fourth N MOS amplifier of the second amplification unit, and
a source of the second N MOS amplifier of the first amplification unit and a source of the fourth N MOS amplifier of the second amplification unit are connected to a ground terminal.

9. The power amplifier of claim 6, wherein a gate of the second P MOS amplifier of the third amplification unit of the second amplification section and a gate of the fourth P MOS amplifier of the fourth amplification unit are connected in common to each other,
the differential signal is input to each of a gate of the first P MOS amplifier of the third amplification unit and a gate of the third P MOS amplifier of the fourth amplification unit, and
a source of the first P MOS amplifier of the third amplification unit and a source of the third P MOS amplifier of the fourth amplification unit are connected in common to a driving power terminal through which a predetermined driving power is supplied.

10. The power amplifier of claim 9, wherein the second amplification section further comprises a first blocking capacitor transmitting the differential signal to the gate of the first P MOS amplifier of the third amplification unit and blocking unnecessary power, and a second blocking capacitor transmitting the differential signal to the gate of the third P MOS amplifier of the fourth amplification unit and blocking unnecessary power.

11. The power amplifier of claim 6, further comprising a first balun converting an input signal being externally applied into the differential signal.

12. The power amplifier of claim 6, further comprising:
a second balun converting the differential signal, amplified by the first amplification section, into a single signal and transmitting the single signal to the power combining section; and
a third balun converting the differential signal, amplified by the second amplification section, into a single signal and transmitting the single signal to the power combining section.
